(19) United States
(12) Patent Application Publication
(10) Pub. No.: US 2024/0167903 A1
(43) Pub. Date: May 23, 2024

(54) APPARATUS AND METHOD FOR MEASURING FLUID PRESSURE WITHIN FLEXIBLE TUBING USING TEMPERATURE-COMPENSATED MAGNETIC SENSOR

(71) Applicant: Zevex, Inc., Salt Lake City, UT (US)

(72) Inventor: Paulius KABISIUS, Kaunas (LT)

(21) Appl. No.: 17/991,987

(22) Filed: Nov. 22, 2022

(51) Int. Cl. G01L 19/04; G01L 9/00

(52) U.S. Cl. CPC G01L 19/04; G01L 9/0029

(57) ABSTRACT

An apparatus for determining fluid pressure within flexible tubing has a magnet and a multidimensional magnetic sensor arranged to detect a magnetic field of the magnet along at least two dimensions. The magnetic sensor and the magnet are arranged such that a location of the magnet relative to the magnetic sensor varies as a function of the fluid pressure within the tubing, and a direction of a magnetic field vector at the magnetic sensor is dependent upon the location of the magnet relative to the magnetic sensor. The magnetic sensor detects at least two magnetic field strengths corresponding to strength of the magnetic field projected along each of the at least two dimensions, and generates an output signal related to the direction of the magnetic field vector at the magnetic sensor. The direction of the magnetic field vector is used as an indicator of the fluid pressure.

### FIELD OF THE DISCLOSURE

The present disclosure relates to measurement of fluid pressure within flexible tubing. In one aspect, the present disclosure relates to a magnetic system for measuring fluid pressure within tubing of an administration set connected to an infusion pump.

### BACKGROUND OF THE DISCLOSURE

Programmable infusion pumps are used to carry out controlled delivery of liquid food for enteral feeding and medications for various purposes, for example pain management. In a common arrangement, an infusion pump receives a disposable administration set comprising a cassette removably received by the pump, and flexible tubing connected to the cassette for providing a fluid delivery path through the pump. In some cases, the cassette is omitted and the tubing is loaded in the pump without a cassette. The administration set may include a pumping segment of tubing acted upon by a pumping mechanism of the pump to force fluid through the tubing to a patient.

Infusion pumps of the type described above may include one or more pressure sensors arranged to measure fluid pressure within the tubing of the administration set. Pressure sensing is an important safety feature because an unexpected variation in fluid pressure may indicate an unsafe condition, such as an occlusion within the tubing that is blocking delivery of food or medication to the patient. In a common arrangement, a pump may have an upstream pressure sensor situated upstream from the pumping mechanism and a downstream pressure sensor situated downstream from the pumping mechanism. If an occlusion occurs at a location upstream from the pressure sensor, a vacuum condition is created and causes radial contraction of the tubing at the sensor location. Conversely, if an occlusion occurs at a location downstream from the pressure sensor, fluid pressure builds and causes radial expansion of the tubing at the sensor location. Various types of pressure sensors are known for measuring pressure by detecting radial contraction and radial expansion of the tubing using a variety of transducer technologies, including optical, magnetic, ultrasonic, and load cell transducers.

With specific regard to magnetic pressure sensors, it is known to provide a magnet arranged to move in response to contraction and expansion of the tubing, and a corresponding Hall effect sensor arranged to generate an output voltage signal proportional to the strength of the magnetic field of the magnet. As the magnet moves closer to the Hall effect sensor, the voltage signal increases, and as the magnet moves away from the Hall effect sensor, the voltage signal decreases. Magnetic pressure sensors of the type described above are economical to manufacture and incorporate into an infusion pump.

However, tubing radial expansion at pressures safe for a patient is also small. This small tubing expansion causes a correspondingly small magnetic field change reported by the Hall sensor. Additionally, the magnetic field generated by a permanent magnet will vary due to changes in temperature. For example, typical sintered NdFeB magnets have temperature coefficients of Br (α)−0.09˜−0.12%/° C. (this value will be specific to each type of magnetic material). Although the variance due to a change in temperature is small, it can be large enough to cause pressure measurement errors unacceptable for use with infusion pumps. Measuring temperature and applying temperature compensation is a method that can be considered to mitigate such errors. However, measuring a temperature directly on a magnet is impractical, and remote measurement will not eliminate temperature errors completely. Inaccurate measurements may lead to false occlusion alarms that are disruptive to the patient's infusion protocol and to the medical staff. Inaccurate pressure measurements may also result in a missed occlusion alarm when an occlusion is actually present, a situation that may have serious safety consequences for the patient.

Another issue with the simple magnetic pressure sensor described above is that magnetic field strength decreases as the inverse square of the distance (1/r²). This nonlinear relationship results in the need for additional calculation in order to linearize the sensor output.

What is needed is a magnetic pressure sensor system for measuring fluid pressure within flexible tubing that has improved temperature compensation and better linearity compared to the existing sensors.

### BRIEF SUMMARY OF THE DISCLOSURE

The present disclosure relates to an apparatus and method for determining a fluid pressure within tubing such as flexible tubing loaded in an infusion pump. For example, determining fluid pressure may allow for detection of occlusions blocking flow through the tubing during delivery of a solution to a patient. More particularly, the present disclosure relates to a fluid pressure sensor wherein a location of a magnet relative to a multidimensional magnetic sensor varies as a result of tube expansion and contraction associated with fluid pressure changes, and output signal information generated by the multidimensional magnetic sensor is used to determine a direction of a magnetic field vector (magnetic field angle) across the multidimensional magnetic sensor corresponding to the fluid pressure. The magnetic field angle is used as an indicator of the fluid pressure. The multidimensional magnetic sensor may be configured to measure magnetic field projections on at least two perpendicular planes.

In some embodiments, an infusion pump includes a pressure sensor as summarized above for measuring fluid pressure within tubing loaded in the infusion pump. The magnet of the pressure sensor has a magnetic field and may be arranged to move relative to the multidimensional magnetic sensor in response to radial contraction and radial expansion of the tubing. The multidimensional magnetic sensor is positioned such that changes in a location of the magnet relative to the multidimensional magnetic sensor provide corresponding changes in the magnetic field strengths detected by the multidimensional magnetic sensor along at least two dimensions. The corresponding field strengths enable determination of the magnetic field angle as an indicator of the fluid pressure.

The relative movement between the magnet and the multidimensional magnetic sensor may be generally linear along a movement axis. For example, the magnet may be affixed to a distal end of a deflectable holder, and a proximal end of the holder may be fixed relative to the multidimensional magnetic sensor, such that movement of the magnet caused by expansion and contraction of the tubing is generally linear along the movement axis. The distal end of the holder carrying the magnet may be resiliently deflectable relative to the proximal end of the holder, and may be spring biased toward engagement with the tubing when the tubing is connected to the infusion pump. In another embodiment, the holder may be arranged such that expansion and contraction of the tubing deflects the holder at a location along the holder between the proximal and distal ends of the holder, such that the distal end of the holder carrying the magnet undergoes an enlarged displacement greater than a radial expansion or radial contraction of the tubing.

The infusion pump may further include a printed circuit board, and the multidimensional magnetic sensor of the first pressure sensor may be mounted to the printed circuit board. The infusion pump may include a processor in electronic communication with the multidimensional magnetic sensor. The processor may be configured to determine a fluid pressure within the tubing based on the output signal from the multidimensional magnetic sensor. The infusion pump may include an alarm configured to generate an alarm signal if the fluid pressure within the tubing exceeds a predetermined threshold.

The infusion pump may have two pressure sensors for measuring fluid pressure within the tubing at a location along the tubing upstream from a pumping mechanism of the infusion pump and at a location along the tubing downstream from the pumping mechanism, respectively.

In another aspect, a method of measuring fluid pressure within flexible tubing of is provided. The method includes providing a multidimensional magnetic sensor and a magnet having a magnetic field, wherein the multidimensional magnetic sensor and the magnet are arranged such that a location of the magnet relative to the multidimensional magnetic sensor varies as a function of the fluid pressure within the flexible tubing, and a direction of a magnetic field vector of the magnetic field at the multidimensional magnetic sensor is dependent upon the location of the magnet relative to the multidimensional magnetic sensor. The method further includes detecting by the multidimensional magnetic sensor at least two magnetic field strengths respectively corresponding to strength of the magnetic field projected along each of at least two dimensions, and determining the direction of the magnetic field vector of the magnetic field at the multidimensional magnetic sensor based on the detected at least two magnetic field strengths. The determined direction of the magnetic field vector of the magnetic field at the multidimensional magnetic sensor is indicative of the fluid pressure within the tubing.

### DESCRIPTION OF THE DRAWINGS

For a fuller understanding of the nature and objects of the disclosure, reference should be made to the following detailed description taken in conjunction with the accompanying drawings, in which:

FIG. 1 is a schematic view illustrating a pressure sensor in accordance with an embodiment of the present disclosure, the pressure sensor including a multidimensional magnetic sensor and a magnet having a magnetic field;

FIG. 2 shows several positions of the multidimensional magnetic sensor relative to the magnet and the magnetic field;

FIG. 3 is a graph of magnetic field strength projections Bx, By, and a magnetic field vector angle α, as a function of the relative position between the multidimensional magnetic sensor and the magnet;

FIG. 4 is a perspective view of an infusion pump formed in accordance with an embodiment of the present disclosure, wherein an administration set is shown installed in the pump;

FIG. 5 is a detailed cross-sectional view through a downstream pressure sensor of the infusion pump shown in FIG. 4, wherein the cross-sectional plane extends longitudinally through the pressure sensor;

FIG. 6 is a top plan view showing an arrangement of an upstream pressure sensor and the downstream pressure sensor in the infusion pump shown in FIG. 4; and

FIG. 7 is a flowchart depicting a method according to another embodiment of the present disclosure.

### DETAILED DESCRIPTION OF THE DISCLOSURE

The present disclosure may be embodied in a pressure sensor for measurement of fluid pressure with flexible tubing. The present disclosure may be embodied in an infusion pump operable to pump fluid through flexible tubing connected to the infusion pump, and in other applications where measurement of fluid pressure with flexible tubing is desired.

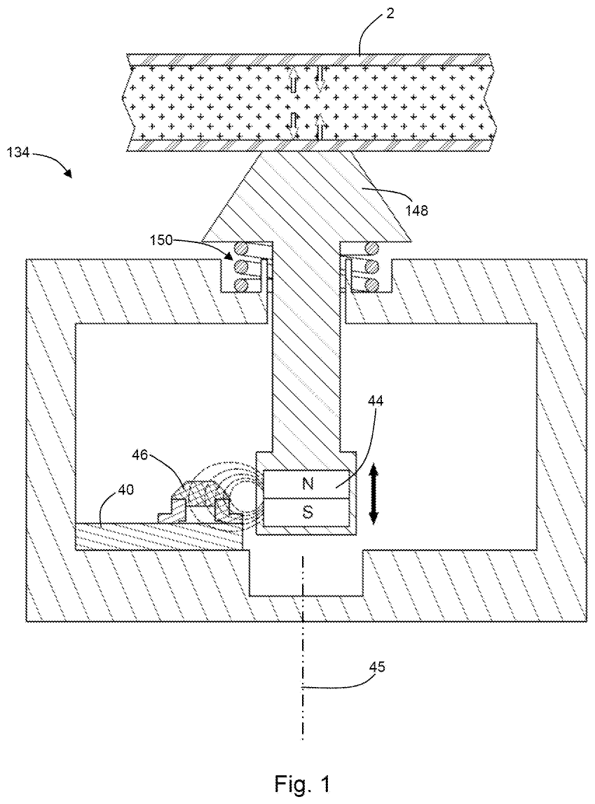

FIG. 1 is a schematic illustration of a pressure sensor 134 for measuring fluid pressure within flexible tubing 2 through which a fluid may be conveyed. Pressure sensor 134 includes a multidimensional magnetic sensor 46 and a magnet 44. The multidimensional magnetic sensor 46 and the magnet 44 are arranged such that a location of the magnet 44 relative to the multidimensional magnetic sensor 46 varies as a function of the fluid pressure within the tubing 2. For example, the magnet 44 may be arranged to move relative to the multidimensional magnetic sensor 46 in response to radial contraction of tubing 2 associated with a decrease in fluid pressure within the tubing, and in response to radial expansion of tubing 2 associated with an increase in fluid pressure within the tubing. As shown in FIG. 1, magnet 44 may be carried by a plunger 148 biased toward direct or indirect contact with tubing 2 by an elastic suspension mechanism 150 such that plunger 148 moves linearly upward in FIG. 1 upon radial contraction of tubing 2 and linearly downward in FIG. 1 upon radial expansion of tubing 2. As plunger 148 moves along a vertical movement axis 45, relative movement occurs between the magnet 44 and the multidimensional magnetic sensor 46. Multidimensional magnetic sensor 46 may be mounted on and electrically connected to a printed circuit board 40 which remains at a fixed location in FIG. 1. Alternatively, the multidimensional magnetic sensor 46 may be carried by plunger 148 and electrically connected to printed circuit board 40, and magnet 44 may be held at a fixed location, such that multidimensional magnetic sensor 46 moves relative to the magnet 44 in response to radial contraction and expansion of tubing 2. The magnet 44 may be a permanent magnet having a magnetic field, illustrated in relevant portion by a series of magnetic field lines in FIG. 1.

The multidimensional magnetic sensor 46 is configured to detect the magnetic field strength of magnet 44 projected along at least two dimensions, for instance two orthogonal spatial dimensions. For example, multidimensional magnetic sensor 46 may be embodied as a two-dimensional (“2D”) magnetic sensor or a three-dimensional (“3D”) magnetic sensor. In some embodiments, the multidimensional magnetic sensor 46 may be two or more magnetic sensors, each arranged to measure a magnetic field strength along a different dimension from the other magnetic sensor(s) (e.g., the respective magnetic sensors may detect magnetic field strengths projected along orthogonal spatial dimensions).

In accordance with the present disclosure, multidimensional magnetic sensor 46 and magnet 44 are arranged such that the magnetic field of magnet 44 impinges on multidimensional magnetic sensor 46, and a direction of a magnetic field vector of the magnetic field at the multidimensional magnetic sensor 46 is dependent upon the location of magnet 44 relative to multidimensional magnetic sensor 46. In a departure from known magnetic pressure sensing systems, the present disclosure uses a direction of the magnetic field vector, not the strength of the magnetic field, as a correlate of the fluid pressure. This has the benefit of eliminating the need for a temperature compensation mechanism. Each dimensional magnetic strength component used to determine the direction of the magnetic field vector is affected by temperature according to the same coefficient associated with the material used for the magnet. Therefore, the temperature effects on each dimensional component cancel one another, and the direction of the magnetic field vector (also referred to as the “magnetic field angle”) is not changed by the temperature of the magnet.

The multidimensional magnetic sensor 46 may be positioned such that changes in a relative location of the magnet 44 provide corresponding changes in the magnetic field strengths detected by the multidimensional magnetic sensor 46 along at least two dimensions, and a direction of a magnetic field vector of the magnetic field at the multidimensional magnetic sensor 46 is dependent upon the location of the magnet 44 relative to the multidimensional magnetic sensor 46. For example, the multidimensional magnetic sensor 46 may be positioned so that the movement axis 45 of the magnet 44 does not cross a center of the multidimensional magnetic sensor 46 (i.e., the multidimensional magnetic sensor 46 is not centered on the movement axis 45). For example, the multidimensional magnetic sensor 46 may be considered to not be centered on the movement axis 45 when a measurement axis of the magnetic sensor (i.e., an axis along one of the measurement dimensions) is not coaxial with the movement axis 45 of magnet 44. In such an arrangement, the magnetic field of magnet 44 impinges on the multidimensional magnetic sensor 46 at a magnetic field angle corresponding to a direction of the magnetic field vector. The magnetic field angle, which changes according to the location of magnet 44 relative to multidimensional magnetic sensor 46, may be determined by, for example, measuring two perpendicular magnetic field strength projections using the multidimensional magnetic sensor 46.

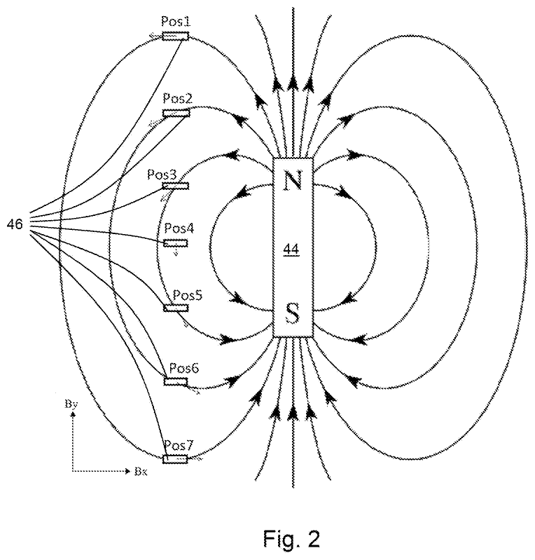

FIG. 2 shows typical magnetic field distribution around magnet 44. In FIG. 2, seven different multidimensional magnetic sensor positions relative to magnet 44 are shown and labeled Pos1-Pos7. These positions are shown for illustrative purposes, and it should be noted that multidimensional magnetic sensor 46 may be located in other positions relative to the magnet 44. An arrow at each position Pos1-Pos7 shows the magnetic field angle at the corresponding position. As may be understood from FIG. 2, the magnetic field strength detected at each relative position of multidimensional magnetic sensor 46 is a vector having a first component Bx along a first direction and a second component By along a second direction perpendicular to the first direction. Multidimensional magnetic sensor 46 is configured to generate an output signal related to the direction of the magnetic field vector of the magnetic field at the multidimensional magnetic sensor 46. For example, the output signal may include information corresponding to the magnetic field strengths Bx and By detected along two orthogonal dimensions which can be used to calculate the magnetic field angle as described below. In some embodiments, the output signal has a first dimension signal corresponding to a magnetic field strength Bx detected along the first dimension and a second dimension signal By corresponding to a magnetic field strength detected along the second dimension. In some embodiments, the output signal is a composite signal derived from the respective magnetic field strength components Bx and By. In some embodiments, the output signal corresponds to the magnetic field angle (e.g., a voltage value which corresponds to a magnetic field angle according to a predetermined relationship). The output signal may undergo processing in a processor or integrated circuit forming part of multidimensional magnetic sensor 46, and/or in a separate processor on printed circuit board 40.

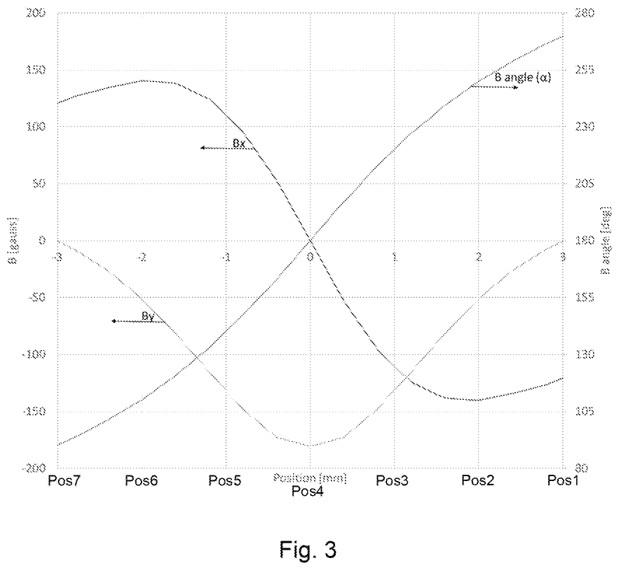

FIG. 3 shows example dimensional components Bx and By of a typical magnetic field as magnet 44 moves along movement axis 45 relative to the multidimensional magnetic sensor 46. Once the magnetic field dimensional components Bx and By have been measured, the angle (α) of the magnetic field (the magnetic field angle) can be calculated according to:

$$α = arctan ( \frac{Bx}{By} ) . \qquad ( 1 )$$

As illustrated in FIG. 3, the magnetic field angle α measured by the multidimensional magnetic sensor 46 depends comparatively linearly on the position of the magnet 44. It is noted that the change in magnetic field angle has much better linearity than other sensing technologies using absolute magnetic field strength at the magnetic sensor, which is proportional to the inverse square of the magnet distance (1/r²) in a nonlinear relationship. In accordance with the present disclosure, the fluid pressure measured by pressure sensor 134 is a correlate of the determined magnetic field angle α. In some embodiments, the magnetic field angle may be further linearized to determine fluid pressure within the tubing.

The fluid pressure may be calculated based on the magnetic field angle α. For example, the fluid pressure may be calculated according to:

P=K1α+K2 (2)

wherein K1 and K2 are constants determined by calibration measurements using known fluid pressures.

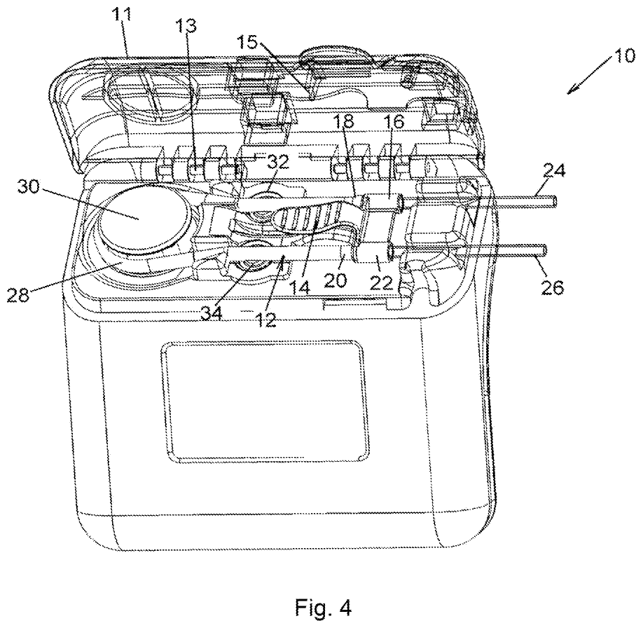

FIG. 4 shows an example infusion pump 10 incorporating pressure sensing technology in accordance with the present disclosure. Infusion pump 10 has a door 11 connected to pump 10 by a hinge 13 on one side of the door and a releasable latch 15 on the other side of the door. An administration set 12 is removably received in pump 10. Administration set 12 includes a cassette 14 having an inflow connector 16, an upstream pumping segment connector 18 in flow communication with inflow connector 16, a downstream pumping segment connector 20, and an outflow connector 22 in flow communication with downstream pumping segment connector 20. Administration set 12 may further include inflow tubing 24 having one end mated to inflow connector 16 and an opposite end (not shown) connected to a fluid source, and outflow tubing 26 having one end connected to outflow connector 22 and an opposite end (not shown) connected to a patient. Finally, administration set 14 may further include a pumping segment of tubing 28 having one end mated to upstream pumping segment connector 18 and an opposite end mated to downstream pumping segment connector 20. It should be noted that the infusion pump shown in FIG. 4 is intended to be illustrative and not limiting. The disclosed sensor configuration may be used with other infusion pump configurations.

In the illustrated embodiment, pump 10 is a rotary peristaltic pump having a motor-driven rotor 30 acting as a pumping mechanism, wherein pumping segment 28 is wrapped around rotor 30 and is engaged by angularly spaced rollers on rotor 30 as the rotor rotates to provide peristaltic pumping action forcing liquid through the tubing of administration set 12. As may be understood by reference to FIG. 4, when rotor 30 rotates in a counter-clockwise direction, liquid is moved from inflow tubing 24 through inflow connector 16 and upstream pumping segment connector 18 to pumping segment 28, and then from pumping segment 28 through downstream pumping segment connector 20 and outflow connector 22 to outflow tubing 26. Although the present disclosure is described in the context of a rotary peristaltic pump having a rotor pumping mechanism, the invention is not limited to this type of infusion pump.

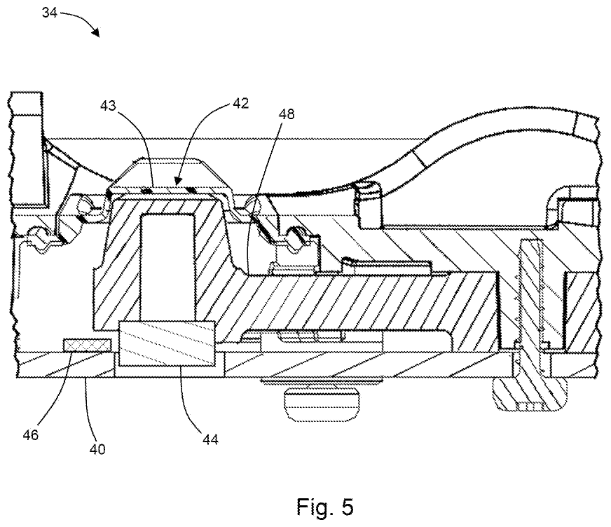

The infusion pump includes a downstream pressure sensor 34 for measuring fluid pressure within the tubing (for example, within the pumping segment 28 of the tubing). Pressure sensor 34 is shown in detail in FIG. 5. Pressure sensor 34 includes a multidimensional magnetic sensor 46 and a magnet 44. The multidimensional magnetic sensor 46 and the magnet 44 are arranged such that a location of the magnet 44 relative to the multidimensional magnetic sensor 46 varies as a function of the fluid pressure within the tubing. For example, magnet 44 may be arranged to move relative to the multidimensional magnetic sensor 46 in response to radial contraction and expansion of tubing pumping segment 28 (not shown in FIG. 5). Pressure sensor 34 may have a tube interface 42 for contacting the tubing. The magnet 44 may be affixed to a holder 48 biased to maintain the tube interface 42 against the tubing (directly or indirectly). The holder 48 may be configured to constrain the movement of the magnet to a generally linear path. For example, the holder 48 depicted in FIG. 5 is configured as an elongated, elastically deformable cantilevered member preloaded to maintain tube interface 42 against the tubing. Holder 48 flexes with radial contraction and expansion of the tubing, thereby moving the magnet 44 generally upward or downward from to the position shown in the FIG. 5. This causes a relative movement between the magnet 44 and the multidimensional magnetic sensor 46. In the embodiment depicted in FIG. 5, the multidimensional magnetic sensor 46 is attached to a printed circuit board 40, which is fixed in positon relative to the body of the pump. In some embodiments, a flexible membrane 43 is provided at the tube interface to prevent liquids and/or other contaminants from entering pressure sensor 34.

Alternatively, the multidimensional magnetic sensor 46 may be arranged to move relative to the magnet 44 in response to radial contraction and expansion of tubing 28.

In a departure from the arrangement illustrated in FIG. 5, holder 48 may be arranged and biased to maintain engagement with loaded tubing at a location between the holder's fixed proximal end and its distal end carrying magnet 44, whereby radial contraction and expansion of the tubing is magnified at the location of magnet 44 for increased sensitivity.

With regard to detection of the magnetic field and measurement of fluid pressure using magnetic field angle α, pressure sensor 34 of infusion pump 10 functions in the same way as pressure sensor 134 described above.

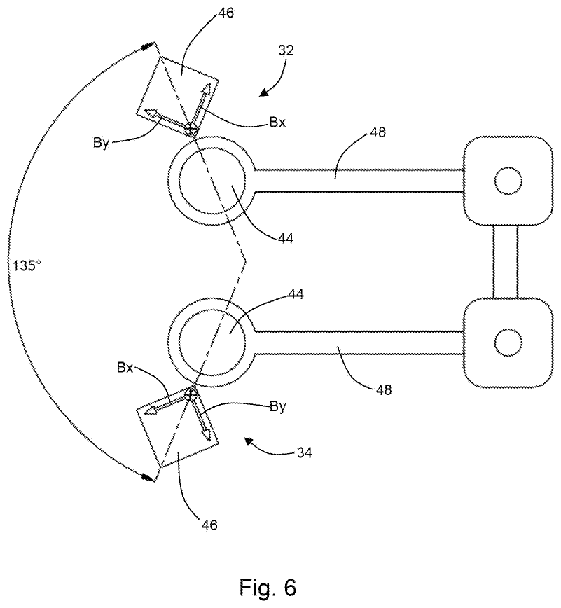

In some embodiments, the infusion pump 10 includes a second pressure sensor 32. Pressure sensor 32 may be arranged as an upstream pressure sensor (i.e., on an “upstream” or “inflow” side of the pumping mechanism 30), and pressure sensor 34 may be arranged as a downstream pressure sensor (i.e., on a “downstream” or “outflow” side of the pumping mechanism). Upstream pressure sensor 32 may be substantially the same as downstream pressure sensor 34. For example, the second pressure sensor may include a multidimensional magnetic sensor and a magnet arranged to move relative to the multidimensional magnetic sensor in response to radial contraction and expansion of the tubing, wherein the multidimensional magnetic sensor is configured to detect a magnetic field along at least two dimensions. FIG. 6 is a top plan view schematically showing an arrangement of upstream pressure sensor 32 and downstream pressure sensor 34. As may be seen in FIG. 6, the respective multidimensional magnetic sensors 46 may be positioned away from one another on the outside of the corresponding magnets 44 and orientated as shown in order to reduce potential crosstalk (i.e., detection of the magnetic field of sensor magnet 44 of upstream pressure sensor 32 by the multidimensional magnetic sensor 46 of downstream pressure sensor 34, and vice versa).

In some embodiments, the infusion pump may have an alarm (i.e., alarm circuit) configured to generate an alarm signal if the fluid pressure meets and/or exceeds a predetermined threshold. The alarm signal may be an audible alarm (buzzer, speaker, horn, etc.), a visible alarm (e.g., strobe, indicator light, flag, etc.), an electronic alarm signal (e.g., a digital alarm flag, alarm sequence, etc.), or any other alarm signal suitable to a particular application.

In some embodiments, the infusion pump may further comprise a processor, for example on printed circuit board 40, in electronic communication with each multidimensional magnetic sensor 46. The processor may be configured to determine fluid pressures based on the output signals from each multidimensional magnetic sensor 46.

The processor may be any suitable processing device or devices made up of one or more integrated circuits, one or more circuits made up of discrete components, or combinations of these. The processor may be configured to run and/or execute a set of instructions or code. For example, the processor can be a general purpose processor, a central processing unit (CPU), an accelerated processing unit (APU), a field-programmable gate array (FPGA), an application specific integrated circuit (ASIC), a digital signal processor (DSP), and/or the like. In some instances, the processor includes one or more modules and/or components. Each module/component executed by the processor can be any combination of hardware-based module/component (e.g., a field-programmable gate array (FPGA), an application specific integrated circuit (ASIC), a digital signal processor (DSP), etc.), software-based module (e.g., a module of computer code stored in the memory and/or in the database, and/or executed at the processor, etc.), and/or a combination of hardware- and software-based modules. Each module/component executed by the processor is capable of performing one or more specific functions/operations as described herein. In some instances, the modules/components included and executed in the processor can be, for example, a process, application, virtual machine, and/or some other hardware or software module/component. The processor can be any suitable processor (or more than one processor) configured to run and/or execute those modules/components.

The processor may be in communication with and/or include a memory. The memory can be, for example, a random-access memory (RAM) (e.g., a dynamic RAM, a static RAM), a flash memory, a removable memory, and/or so forth. In some instances, instructions associated with performing the operations described herein (e.g., calculating magnetic field angle and fluid pressure) can be stored within the memory and/or a storage medium (which, in some embodiments, includes a database in which the instructions are stored) and the instructions are executed at the processor.

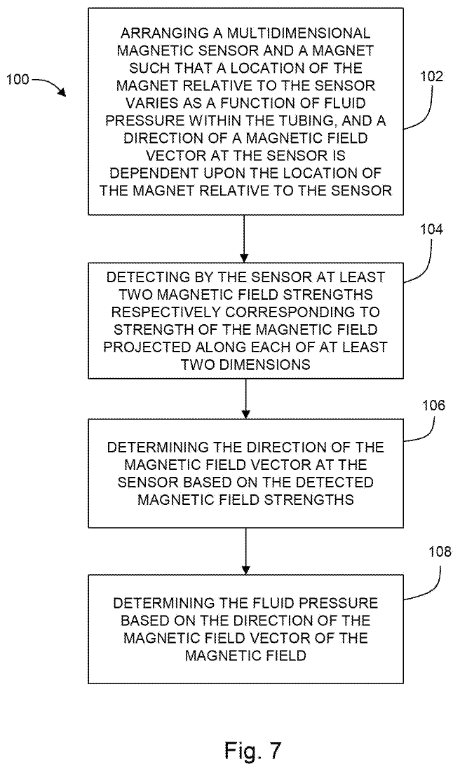

With reference to FIG. 7, in another aspect, the present disclosure may be embodied as a method 100 of measuring fluid pressure within tubing. Method 100 begins with step 102, which is providing a multidimensional magnetic sensor and a magnet having a magnetic field, wherein the multidimensional magnetic sensor and the magnet are arranged such that a location of the magnet relative to the multidimensional magnetic sensor varies as a function of the fluid pressure within the flexible tubing, and a direction of a magnetic field vector of the magnetic field at the multidimensional magnetic sensor is dependent upon the location of the magnet relative to the multidimensional magnetic sensor. The next step 104 includes detecting by the multidimensional magnetic sensor at least two magnetic field strengths respectively corresponding to strength of the magnetic field projected along each of at least two dimensions. Step 104 is followed by step 106, in which the direction of the magnetic field vector of the magnetic field at the multidimensional magnetic sensor is determined based on the detected at least two magnetic field strengths. Finally, the fluid pressure may be determined in step 108 based on the direction of the magnetic field vector.

Although the present disclosure has been described with respect to one or more particular embodiments, it will be understood that other embodiments of the present disclosure may be made without departing from the scope of the present disclosure.

What is claimed is:

1. An infusion pump operable to pump fluid through tubing connected to the infusion pump, wherein the infusion pump comprises:
a pressure sensor for measuring fluid pressure within the tubing, the pressure sensor comprising:
a magnet having a magnetic field; and
a multidimensional magnetic sensor arranged to detect the magnetic field along at least two dimensions;
wherein the multidimensional magnetic sensor and the magnet are arranged such that a location of the magnet relative to the multidimensional magnetic sensor varies as a function of the fluid pressure within the tubing, and a direction of a magnetic field vector of the magnetic field at the multidimensional magnetic sensor is dependent upon the location of the magnet relative to the multidimensional magnetic sensor; and
wherein the multidimensional magnetic sensor detects at least two magnetic field strengths respectively corresponding to strength of the magnetic field projected along each of the at least two dimensions, and generates an output signal related to the direction of the magnetic field vector of the magnetic field at the multidimensional magnetic sensor.

2. The infusion pump according to claim 1, wherein the magnet is arranged to move relative to the multidimensional magnetic sensor along an at least generally linear movement axis in response to radial expansion and radial contraction of the tubing.

3. The infusion pump according to claim 2, further comprising a holder having a proximal end fixed relative to the multidimensional magnetic sensor and a distal end spaced from the proximal end, wherein the magnet is mounted at the distal end of the holder and the distal end of the holder is displaceable relative to the multidimensional magnetic sensor.

4. The infusion pump according to claim 3, wherein the distal end of the holder is resiliently deflectable relative to the proximal end of the holder, and the distal end of the holder is spring biased toward engagement with the tubing when the tubing is connected to the infusion pump.

5. The infusion pump according to claim 2, wherein the multidimensional magnetic sensor is not centered on the movement axis of the magnet.

6. The infusion pump according to claim 1, wherein the output signal comprises a first dimension signal corresponding to a first magnetic field strength detected along a first dimension of the at least two dimensions and a second dimension signal corresponding to a second magnetic field strength detected along a second dimension of the at least two dimensions.

7. The infusion pump according to claim 6, further comprising a processor in electronic communication with the multidimensional magnetic sensor, wherein the processor is configured to determine a magnetic field angle corresponding to the direction of the magnetic field vector of the magnetic field at the multidimensional magnetic sensor based on the output signal.

8. The infusion pump according to claim 1, wherein the output signal is derived from a first magnetic field strength detected along a first dimension of the at least two dimensions and a second magnetic field strength detected along a second dimension of the at least two dimensions.

9. The infusion pump according to claim 8, wherein the output signal represents a magnetic field angle corresponding to the direction of the magnetic field vector of the magnetic field at the multidimensional magnetic sensor.

10. The infusion pump according to claim 1, wherein a first dimension of the at least two dimensions is perpendicular to a second dimension of the at least two dimensions.

11. The infusion pump according to claim 1, wherein the multidimensional magnetic sensor comprises a first magnetic sensor arranged to detect magnetic field strength along a first dimension of the at least two dimensions and a second magnetic sensor arranged to detect magnetic field strength along a second dimension of the at least two dimensions.

12. The infusion pump according to claim 1, wherein the infusion pump comprises two of the pressure sensors and a pumping mechanism arranged to act on the tubing to pump fluid in a flow direction through the tubing, wherein one of the two pressure sensors is arranged to measure fluid pressure within the tubing at a location upstream from the pumping mechanism and another of the two pressure sensors is arranged to measure fluid pressure within the tubing at a location downstream from the pumping mechanism, and wherein the respective magnets of the two pressure sensors are closer to one another than the respective multidimensional magnetic sensors of the two pressure sensors.

13. A pressure sensor for measuring fluid pressure within flexible tubing connected to the pressure sensor, the pressure sensor comprising:
a magnet having a magnetic field; and
a multidimensional magnetic sensor arranged to detect the magnetic field along at least two dimensions;
wherein the multidimensional magnetic sensor and the magnet are arranged such that a location of the magnet relative to the multidimensional magnetic sensor varies as a function of the fluid pressure within the tubing, and a direction of a magnetic field vector of the magnetic field at the multidimensional magnetic sensor is dependent upon the location of the magnet relative to the multidimensional magnetic sensor; and
wherein the multidimensional magnetic sensor detects at least two magnetic field strengths respectively corresponding to strength of the magnetic field projected along each of the at least two dimensions, and generates an output signal related to the direction of the magnetic field vector of the magnetic field at the multidimensional magnetic sensor.

14. The pressure sensor according to claim 13, further comprising a processor in electronic communication with the multidimensional magnetic sensor, wherein the processor is configured to determine a magnetic field angle corresponding to the direction of the magnetic field vector of the magnetic field at the multidimensional magnetic sensor based on the output signal.

15. A method of measuring fluid pressure within flexible tubing, the method comprising:
providing a multidimensional magnetic sensor and a magnet having a magnetic field, wherein the multidimensional magnetic sensor and the magnet are arranged such that a location of the magnet relative to the multidimensional magnetic sensor varies as a function of the fluid pressure within the flexible tubing, and a direction of a magnetic field vector of the magnetic field at the multidimensional magnetic sensor is dependent upon the location of the magnet relative to the multidimensional magnetic sensor;
detecting by the multidimensional magnetic sensor at least two magnetic field strengths respectively corresponding to strength of the magnetic field projected along each of at least two dimensions; and
determining the direction of the magnetic field vector of the magnetic field at the multidimensional magnetic sensor based on the detected at least two magnetic field strengths;
wherein the direction of the magnetic field vector of the magnetic field at the multidimensional magnetic sensor is indicative of the fluid pressure within the tubing.

16. The method according to claim 15, wherein the magnet moves along an at least generally linear movement axis relative to the multidimensional magnetic sensor in response to the radial expansion and the radial contraction of the tubing.
